(19) United States
(12) Patent Application Publication
(10) Pub. No.: US 2026/0080219 A1
(43) Pub. Date: Mar. 19, 2026

(54) TRAINING DEVICE, INFORMATION PROCESSING APPARATUS, SUBSTRATE PROCESSING APPARATUS, SUBSTRATE PROCESSING SYSTEM, TRAINING METHOD AND PROCESSING CONDITION DETERMINING METHOD

(71) Applicant: SCREEN HOLDINGS CO., LTD., Kyoto (JP)

(72) Inventor: Masahiro TOKUYAMA, Kyoto-shi, Kyoto (JP)

(21) Appl. No.: 19/110,056

(22) PCT Filed: Aug. 4, 2023
(86) PCT No.: PCT/JP2023/028655

§ 371 Date: Mar. 7, 2025

(30) Foreign Application Priority Data
Sep. 26, 2022 (JP) 2022-153151

(51) Int. Cl. G06N 3/0464; H01L 21/67

(52) U.S. Cl. CPC G06N 3/0464; H10P 72/0604

(57) ABSTRACT

A training device includes an experimental data acquirer that acquires a first processing amount indicating a difference between a film thickness obtained before a process for a film and a film thickness obtained after the process for the film, after a substrate processing apparatus is driven according to processing conditions including a variable condition that varies over time and executes the process for the film, and a model generator that generates a learning model, with the learning model executing machine learning using training data that includes the variable condition and the first processing amount corresponding to the processing conditions and predicting a second processing amount that indicates a difference between a film thickness obtained before the process for the film and a film thickness obtained after the process for the film wherein the learning model includes a first convolutional neural network.

### TECHNICAL FIELD

The present invention relates to a training device, an information processing apparatus, a substrate processing apparatus, a substrate processing system, a training method and a processing condition determining method. In particular, the present invention relates to a training device that generates a learning model for simulating a process executed by a substrate processing apparatus according to processing conditions, an information processing apparatus that determines processing conditions using the learning model, a substrate processing apparatus including the information processing apparatus, a substrate processing system including the information processing apparatus and the training device, a training method executed by the training device, and a processing condition determining method executed by the information processing apparatus.

### BACKGROUND ART

In a semiconductor manufacturing process, there is a cleaning process. In the cleaning process, the thickness of a film formed on a substrate is adjusted by an etching process of supplying a chemical liquid to the substrate. In this film-thickness adjustment, it is important to execute the etching process such that the surface of the substrate is uniform, or to flatten the surface of the substrate by the etching process. In a case in which an etching liquid is discharged from a nozzle to a portion of the substrate, the nozzle is required to be moved in a radial direction with respect to the substrate.

The Patent Document 1 describes a liquid processing device that is capable of executing an etching process on a substrate by discharging an etching liquid to the substrate from a nozzle. Patent Document 1 describes, by way of example, that in order to make the in-plane temperature distribution of a wafer uniform while an etching process is executed on the center area of a substrate, an etching liquid is discharged while an etching nozzle is moved back and forth repeatedly between a first position and a second position, with the first position being a position at which the etching nozzle is located when the discharged etching liquid passes through the center of the wafer and which is close to the center and with the second position being a position closer to the peripheral portion of the wafer than the position closer to the center.

The etching process is a complicated process in which a processing amount indicating how much a film is processed changes due to differences in work for moving a nozzle. Further, the processing amount indicating how much the film is processed in the etching process is provided after the substrate is processed. Therefore, trial and error by an engineer are required to set the work for moving a nozzle. Determination for optimal nozzle work is costly and time consuming.

### PATENT DOCUMENT 1

JP 2015-103656 A

### SUMMARY OF INVENTION

### Technical Problem

On the other hand, it is desired to more sufficiently complicate the work for moving a nozzle. The work for moving a nozzle is time-series data representing a position that changes over time. When the work for moving a nozzle is complicated, the sampling intervals are shortened, and thus the number of dimensions of the time-series data increases. In general, when the number of dimensions of training data increases, the number of data sets required for machine learning increases exponentially. Therefore, the number of dimensions of the training data increases, so that it is difficult to optimize a learning model obtained by machine learning. Further, because the etching process is a complicated process, the number of nozzle works suitable for a target processing amount is not limited to 1, and the number of nozzle works may be 2 or more than 2.

One object of the present invention is to provide a training device, a training method and a substrate processing system suitable for machine learning using a condition for a substrate process, with the condition changing over time.

Further, another object of the present invention is to provide an information processing apparatus, a substrate processing apparatus, a substrate processing system and a processing condition determining method that enable presentation of a plurality of processing conditions for a processing result of a complicated process of processing a substrate.

### Solution to Problem

A training device according to one aspect of the present invention includes an experimental data acquirer that acquires a first processing amount indicating a difference between a film thickness obtained before a process for a film and a film thickness obtained after the process for the film, after a substrate processing apparatus is driven according to processing conditions including a variable condition that varies over time and executes the process for the film, the substrate processing apparatus processing the film by supplying a processing liquid to the substrate on which the film is formed, and a model generator that generates a learning model, the learning model executing machine learning using training data that includes the variable condition and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus, wherein the learning model includes a first convolutional neural network.

A substrate processing apparatus according to another aspect of the present invention managing an information processing apparatus, wherein the substrate processing apparatus processes a film by supplying a processing liquid to a substrate on which the film is formed according to processing conditions including a variable condition that varies over time, and includes a processing condition determiner that determines processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus, the learning model includes a first convolutional neural network and is an inference model that has executed machine learning using training data, with the training data including the variable condition included in the processing conditions according to which the substrate processing apparatus has executed a process for the film, and a first processing amount indicating a difference between a film thickness obtained before the process for the film and a film thickness obtained after the process for the film in regard to the film that is formed on the substrate and has been processed by the substrate processing apparatus, and the processing condition determiner, in a case in which a temporary variable condition is provided to the learning model and the second processing amount predicted by the learning model satisfies an allowable condition, determines processing conditions including the temporary variable condition as processing conditions for driving the substrate processing apparatus.

A substrate processing system according to yet another aspect of the present invention that manages a substrate processing apparatus, includes a training device and an information processing apparatus, wherein the substrate processing apparatus processes a film by supplying a processing liquid to a substrate on which the film is formed according to processing conditions including a variable condition that varies over time, the training device includes an experimental data acquirer that acquires a first processing amount indicating a difference between a film thickness obtained before a process for the film and a film thickness obtained after the process for the film, after the substrate processing apparatus is driven according to processing conditions and executes the process for the film formed on the substrate, and a model generator that generates a learning model, the learning model executing machine learning using training data that includes the variable condition and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus, the learning model includes a first convolutional neural network, the information processing apparatus includes a processing condition determiner that determines processing conditions for driving the substrate processing apparatus using the learning model generated by the training device, and the processing condition determiner, in a case in which a temporary variable condition is provided to the learning model generated by the training device and the second processing amount predicted by the learning model satisfies an allowable condition, determines processing conditions including the temporary variable condition as processing conditions for driving the substrate processing apparatus.

A training method according to yet another aspect of the present invention of causing a computer to execute the processes of acquiring a first processing amount indicating a difference between a film thickness obtained before a process for a film and a film thickness obtained after the process for the film, after a substrate processing apparatus is driven according to processing conditions including a variable condition that varies over time and executes the process for the film, the substrate processing apparatus processing the film by supplying a processing liquid to the substrate on which the film is formed, and generating a learning model, the learning model executing machine learning using training data that includes the variable condition and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus, wherein the learning model includes a first convolutional neural network.

A processing condition determining method according to yet another aspect of the present invention executed by a computer that manages a substrate processing apparatus, wherein the substrate processing apparatus processes a film by supplying a processing liquid to a substrate on which the film is formed according to processing conditions including a variable condition that varies over time, the processing condition determining method includes a process of determining processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus, the learning model includes a first convolutional neural network and is an inference model that has executed machine learning using training data, with the training data including the variable condition included in the processing conditions according to which the substrate processing apparatus has executed a process for the film, and a first processing amount indicating a difference between a film thickness obtained before the process for the film and a film thickness obtained after the process for the film in regard to the film that is formed on the substrate and has been processed by the substrate processing apparatus, and the process of determining processing conditions, in a case in which a temporary variable condition is provided to the learning model and the second processing amount predicted by the learning model satisfies an allowable condition, includes determining processing conditions including the temporary variable condition as processing conditions for driving the substrate processing apparatus.

### Advantageous Effects of Invention

It is possible to provide a training device, a training method and a substrate processing system suitable for machine learning using a condition for a substrate process, with the condition changing over time.

It is possible to provide an information processing apparatus, a substrate processing apparatus, a substrate processing system and a processing condition determining method that enable presentation of a plurality of processing conditions for a processing result of a complicated process of processing a substrate.

### BRIEF DESCRIPTION OF THE DRAWINGS

FIG. 1 is a diagram for explaining the configuration of a substrate processing system according to one embodiment of the present invention.

FIG. 2 is a diagram showing one example of the configuration of an information processing apparatus.

FIG. 3 is a diagram showing one example of the configuration of a training device.

FIG. 4 is a diagram showing one example of the functional configuration of the substrate processing system.

FIG. 5 is a diagram showing one example of a film-thickness characteristic.

FIG. 6 is a diagram for explaining a learning model.

FIG. 7 is a flowchart showing one example of a flow of a training process.

FIG. 8 is a flowchart showing one example of a flow of a processing condition determining process.

FIG. 9 is a flowchart showing one example of a flow of an additional training process.

FIG. 10 is a first diagram for explaining a learning model according to another embodiment.

FIG. 11 is a second diagram for explaining the learning model according to the other embodiment.

### DESCRIPTION OF EMBODIMENTS

A substrate processing system according to one embodiment of the present invention will be described below with reference to the drawings. In the following description, a substrate refers to a semiconductor substrate (semiconductor wafer), a substrate for an FPD (Flat Panel Display) such as a liquid crystal display device or an organic EL (Electro Luminescence) display device, a substrate for an optical disc, a substrate for a magnetic disc, a substrate for a magneto-optical disc, a substrate for a photomask, a ceramic substrate, a substrate for a solar battery, or the like.

### 1. Overall Configuration of Substrate Processing System

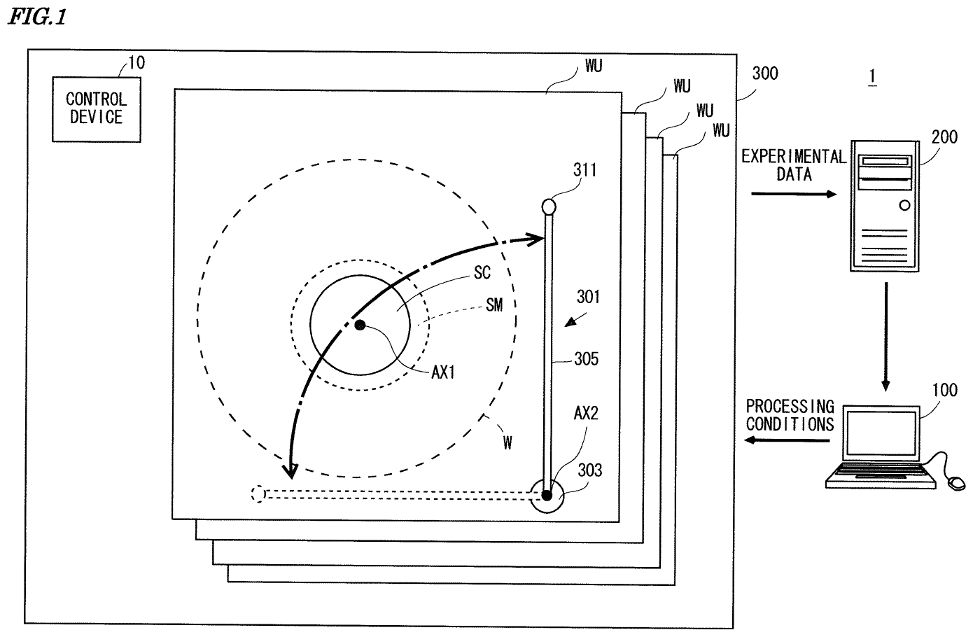

FIG. 1 is a diagram for explaining the configuration of the substrate processing system according to the one embodiment of the present invention. The substrate processing system 1 of FIG. 1 includes an information processing apparatus 100, a training device 200 and a substrate processing apparatus 300. The training device 200 is a server, for example, and the information processing apparatus 100 is a personal computer, for example.

The training device 200 and the information processing apparatus 100 are used to manage the substrate processing apparatus 300. The number of substrate processing apparatuses 300 managed by the training device 200 and the information processing apparatus 100 is not limited to one, and a plurality of substrate processing apparatuses 300 may be managed by the training device 200 and the information processing apparatus 100.

In the substrate processing system 1 according to the present embodiment, the information processing apparatus 100, the training device 200 and the substrate processing apparatus 300 are connected to one another by a wired communication line, a wireless communication line or a communication network. The information processing apparatus 100, the training device 200 and the substrate processing apparatus 300 are respectively connected to a network and can transmit and receive data to and from one another. As the network, a Local Area Network (LAN) or a Wide Area Network (WAN) is used, for example. Further, the network may be the Internet. Further, the information processing apparatus 100 and the substrate processing apparatus 300 may be connected to each other via a dedicated communication network. The connection state of the network may be wired or wireless.

The training device 200 is not necessarily required to be connected to the substrate processing apparatus 300 or the information processing apparatus 100 via a communication line or a communication network. In this case, the data generated in the substrate processing apparatus 300 may be transferred to the training device 200 via a recording medium. Further, the data generated in the training device 200 may be transferred to the information processing apparatus 100 via a recording medium.

In the substrate processing apparatus 300, a display device, a speech output device and an operation unit (not shown) are provided. The substrate processing apparatus 300 runs according to predetermined processing conditions (processing recipe) of the substrate processing apparatus 300.

### 2. Outline of Substrate Processing Apparatus

The substrate processing apparatus 300 includes a control device 10 and a plurality of substrate processing units WU. The control device 10 controls the plurality of substrate processing units WU. Each of the plurality of substrate processing units WU process a substrate W by supplying a processing liquid to the substrate W on which a film is formed. The processing liquid includes an etching liquid, and the substrate processing unit WU executes an etching process. The etching liquid is a chemical liquid. The etching liquid is a fluoronitric acid (a liquid mixture of hydrofluoric acid (HF) and nitric acid (HNO₃), hydrofluoric acid, buffered hydrofluoric acid (BHF), ammonium fluoride, HFEG (a liquid mixture of hydrofluoric acid and ethylene glycol) or phosphoric acid (H₃PO₄), for example.

The substrate processing unit WU includes a spin chuck SC, a spin motor SM, a nozzle 311 and a nozzle moving mechanism 301. The spin chuck SC horizontally holds the substrate W. The spin motor SM has a first rotation axis AX1. The first rotation axis AX1 extends in an upward-and-downward direction. The spin chuck SC is attached to the upper end portion of the first rotation axis AX1 of the spin motor SM. When the spin motor SM rotates, the spin chuck SC rotates about the first rotation axis AX1. The spin motor SM is a stepping motor. The substrate W held by the spin chuck SC rotates about the first rotation axis AX1. Therefore, the rotation speed of the substrate W is the same as the rotation speed of the stepping motor. In a case in which an encoder that generates a rotation speed signal indicating the rotation speed of the spin motor is provided, the rotation speed of the substrate W may be acquired from the rotation speed signal generated by the encoder. In this case, a motor other than the stepping motor can be used as the spin motor.

The nozzle 311 supplies the etching liquid to the substrate W. The etching liquid is supplied from an etching liquid supplier (not shown) to the nozzle 311, and the nozzle 311 discharges the etching liquid to the rotating substrate W.

The nozzle moving mechanism 301 moves the nozzle 311 in a substantially horizontal direction. Specifically, the nozzle moving mechanism 301 has a nozzle motor 303 having a second rotation axis AX2 and a nozzle arm 305. The nozzle motor 303 is arranged such that the second rotation axis AX2 extends in a substantially vertical direction. The nozzle arm 305 has a longitudinal shape extending linearly. One end of the nozzle arm 305 is attached to the upper end of the second rotation axis AX2 such that the longitudinal direction of the nozzle arm 305 is different from the direction of the second rotation axis AX2. The nozzle 311 is attached to the other end of the nozzle arm 305 such that the discharge port of the nozzle 311 is directed downwardly.

When the nozzle motor 303 works, the nozzle arm 305 rotates about the second rotation axis AX2 in a horizontal plane. Thus, the nozzle 311 attached to the other end of the nozzle arm 305 moves (turns) in the horizontal direction about the second rotation axis AX2. The nozzle 311 discharges the etching liquid toward the substrate W while moving in the horizontal direction. The nozzle motor 303 is a stepping motor, for example.

The control device 10 includes a CPU (Central Processing Unit) and a memory, and controls the substrate processing apparatus 300 as a whole by execution by the CPU of a program stored in the memory. The control device 10 controls the spin motor SM and the nozzle motor 303.

The training device 200 receives experimental data from the substrate processing apparatus 300, causes a learning model to execute machine learning using the experimental data, and outputs the trained learning model to the information processing apparatus 100.

The information processing apparatus 100 determines processing conditions for processing a substrate to be processed by the substrate processing apparatus 300 using the trained learning model. The information processing apparatus 100 outputs the determined processing conditions to the substrate processing apparatus 300.

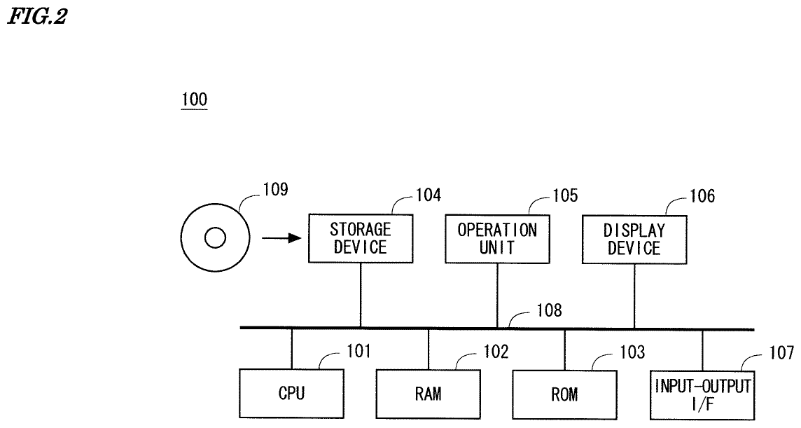

FIG. 2 is a diagram showing one example of the configuration of the information processing apparatus. With reference to FIG. 2, the information processing apparatus 100 includes a CPU 101, a RAM (Random Access Memory) 102, a ROM (Read Only Memory) 103, a storage device 104, an operation unit 105, a display device 106 and an input-output interface (I/F) 107. The CPU 101, the RAM 102, the ROM 103, the storage device 104, the operation unit 105, the display device 106 and the input-output I/F 107 are connected to a bus 108.

The RAM 102 is used as a work area for the CPU 101. A system program is stored in the ROM 103. The storage device 104 includes a storage medium such as a hard disc or a semiconductor memory and stores a program. The program may be stored in the ROM 103 or another external storage device.

A CD-ROM 109 is attachable to and detachable from the storage device 104. A recording medium storing a program to be executed by the CPU 101 is not limited to the CD-ROM 109. It may be an optical disc (MO (Magnetic Optical Disc)/MD (Mini Disc)/DVD (Digital Versatile Disc)), an IC card, an optical card, and a semiconductor memory such as a mask ROM or an EPROM (Erasable Programmable ROM). Further, the CPU 101 may download the program from a computer connected to the network and store the program in the storage device 104, or the computer connected to the network may write the program in the storage device 104, and the program stored in the storage device 104 may be loaded into the RAM 102 and executed in the CPU 101. The program referred to here includes not only a program directly executable by the CPU 101 but also a source program, a compressed program, an encrypted program and the like.

The operation unit 105 is an input device such as a keyboard, a mouse or a touch panel. A user can provide a predetermined instruction to the information processing apparatus 100 by operating the operation unit 105. The display device 106 is a display device such as a liquid crystal display device and displays a GUI (Graphical User Interface) or the like for receiving an instruction from the user. The input-output I/F 107 is connected to the network.

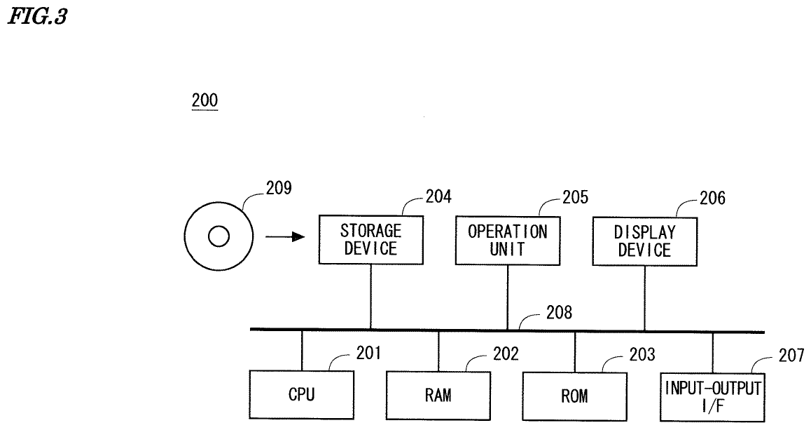

FIG. 3 is a diagram showing one example of the configuration of the training device. With reference to FIG. 3, the training device 200 includes a CPU 201, a RAM 202, a ROM 203, a storage device 204, an operation unit 205, a display device 206 and an input-output I/F 207. The CPU 201, the RAM 202, the ROM 203, the storage device 204, the operation unit 205, the display device 206 and the input-output I/F 207 are connected to a bus 208.

The RAM 202 is used as a work area for the CPU 201. A system program is stored in the ROM 203. The storage device 204 includes a storage medium such as a hard disc or a semiconductor memory and stores a program. The program may be stored in the ROM 203 or another external storage device. A CD-ROM 209 is attachable to and detachable from the storage device 204.

The operation unit 205 is an input device such as a keyboard, a mouse or a touch panel. The input-output I/F 207 is connected to the network.

### 3. Functional Configuration of Substrate Processing System

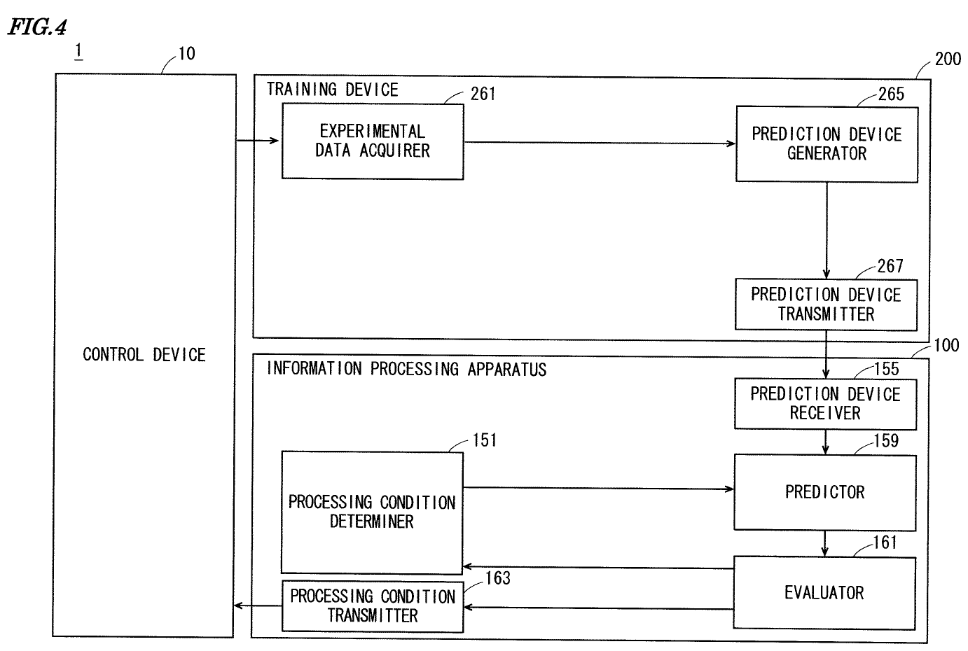

FIG. 4 is a diagram showing one example of the functional configuration of a substrate processing system. With reference to FIG. 4, the control device 10 included in the substrate processing apparatus 300 controls the substrate processing unit WU to process the substrate W according to processing conditions. The processing conditions are the conditions for processing the substrate W in a predetermined processing period of time. The processing period of time is the period of time defined for a substrate process. In the present embodiment, the processing period of time is the period of time during which the nozzle 311 discharges the etching liquid to the substrate W.

In the present embodiment, the processing conditions include a temperature of the etching liquid, a concentration of the etching liquid, a flow rate of the etching liquid, the number of rotations of the substrate W, and the relative positions of the nozzle 311 and the substrate W with respect to each other. The processing conditions include a variable condition that varies over time. In the present embodiment, the variable condition is the relative positions of the nozzle 311 and the substrate W with respect to each other. The relative positions are indicated by a rotation angle of the nozzle motor 303. The processing conditions include a fixed condition that does not vary over time. In the present embodiment, fixed conditions include a temperature of the etching liquid, a concentration of the etching liquid, a flow rate of the etching liquid and the number of rotations of the substrate W.

The training device 200 causes a learning model to learn training data, and generates an inference model for predicting an etching profile based on processing conditions. Hereinafter, an inference model generated by the training device 200 is referred to as a prediction device.

The training device 200 includes an experimental data acquirer 261, a prediction device generator 265 and a prediction device transmitter 267. The functions included in the training device 200 are implemented by execution by the CPU 201 included in the training device 200 of a training program stored in the RAM 202.

The experimental data acquirer 261 acquires experimental data from the substrate processing apparatus 300. The experimental data includes processing conditions used in a case in which the substrate processing apparatus 300 actually processes the substrate W, and film-thickness characteristics of a film formed on the substrate W before and after the process. The film-thickness characteristic is indicated by the film thickness of a film formed on the substrate W at each of a plurality of different positions in a radial direction of the substrate W.

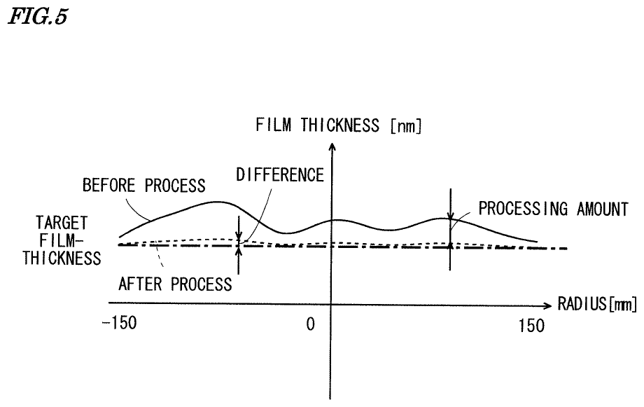

FIG. 5 is a diagram showing one example of the film-thickness characteristic. With reference to FIG. 5, the abscissa indicates a position in the radial direction of the substrate, and the ordinates indicates a film thickness. The origin of the abscissa indicates the center of the substrate. The film thickness of a film formed on the substrate W before the substrate W is processed by the substrate processing apparatus 300 is indicated by the solid line. The substrate processing apparatus 300 executes a process of supplying an etching liquid according to processing conditions, thereby adjusting the film thickness of the film formed on the substrate W. The film thickness of the film formed on the substrate W after the substrate W is processed by the substrate processing apparatus 300 is indicated by the dotted line.

The difference between the film thickness of the film formed on the substrate W before the substrate W is processed by the substrate processing apparatus 300 and the film thickness of the film formed on the substrate W after the substrate W is processed by the substrate processing apparatus 300 is a processing amount (etching amount). The processing amount indicates the film thickness by which the film is reduced in the process of supplying the etching liquid by the substrate processing apparatus 300. The distribution in the radial direction of the processing amount is referred to as an etching profile. The etching profile is represented by the processing amount at each of the plurality of different positions in the radial direction of the substrate W.

Further, it is desirable that the film thickness of a film formed by the substrate processing apparatus 300 is uniform over the entire surface of the substrate W. Therefore, a target film-thickness is defined for the process executed by the substrate processing apparatus 300. The target film-thickness is indicated by the one-dot and dash line. A deviation characteristic is the difference between the film thickness of a film formed on the substrate W after the substrate W is processed by the substrate processing apparatus 300 and the target film-thickness. The deviation characteristic includes the difference generated at each of the plurality of positions in the radial direction of the substrate W.

Referring back to FIG. 4, the prediction device generator 265 receives the experimental data from the experimental data acquirer 261. The prediction device generator 265 generates a prediction device by causing a neural network to execute supervised learning using training data.

Specifically, the training data includes input data and ground truth data. The input data includes a variable condition included in the processing conditions of the experimental data, and fixed conditions other than the variable condition of the processing conditions included in the experimental data. The ground truth data includes an etching profile. The etching profile is the difference between the film-thickness characteristic of a film that is obtained before the process and included in the experimental data, and the film-thickness characteristic of the film that is obtained after the process and included in the experimental data. The etching profile included in the ground truth data is one example of a first processing amount. The prediction device generator 265 inputs the input data to the learning model that is the basis of the prediction device, and determines parameters of the learning model such that the difference between the output of the learning model and the ground truth data is small. The prediction device generator 265 generates, as a prediction device, a trained model in which the parameters set in the trained learning model are incorporated. The prediction device is an inference program in which the parameters set in the trained model are incorporated. The prediction device generator 265 transmits the prediction device to the information processing apparatus 100.

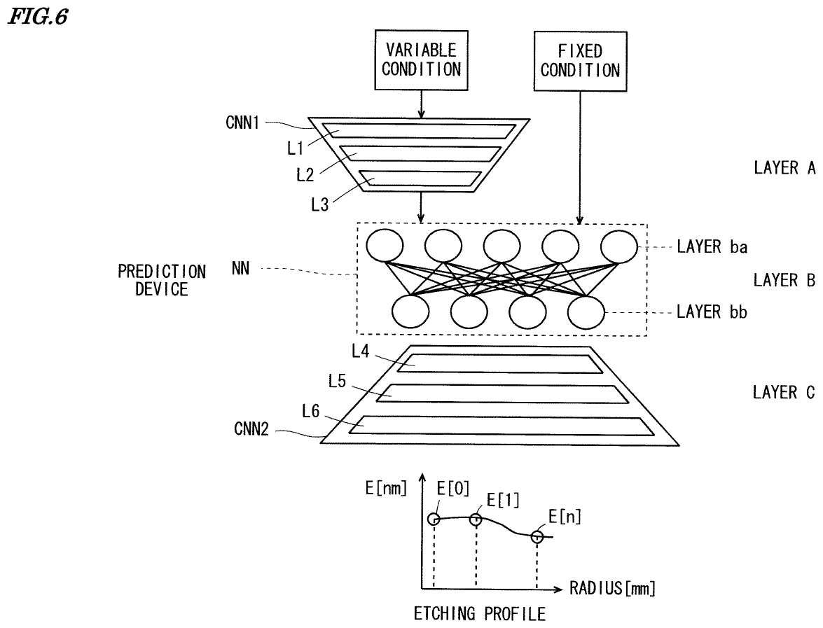

FIG. 6 is a diagram for explaining a learning model. With reference to FIG. 6, in the learning model, layers A to C are provided in this order from the input side to the output side (from the upper layer to the lower layer). A first convolutional neural network CNN1 is provided in the layer A, a fully-connected neural network NN is provided in the layer B, and a second convolutional neural network CNN2 is provided in the layer C.

A variable condition is input to the first convolutional neural network CNN1. The output of the first convolutional neural network CNN1 and fixed conditions are input to the fully-connected neural network NN. The output of the fully-connected neural network NN is input to the second convolutional neural network CNN2.

The first convolutional neural network CNN1 includes a plurality of layers. In the present embodiment, the first convolutional neural network CNN1 includes three layers. In the first convolutional neural network CNN1, a first layer L1, a second layer L2 and a third layer L3 are provided in this order from the input side (upper layer side) to the output side (lower layer side). While the three layers are included as a plurality of layers in the description in the present embodiment, three or more layers may be included.

Each of the first layer L1, the second layer L2 and the third layer L3 includes a convolution layer and a pooling layer. The convolution layer includes a plurality of filters. In the convolution layer, a plurality of filters are used. The pooling layer compresses the output of the convolution layer. The number of filters of the convolution layer of the second layer L2 is set to twice of the number of filters of the convolution layer of the first layer L1. The number (count) of filters of the convolution layer of the third layer L3 is set to twice of the number (count) of filters of the convolution layer of the second layer L2. Therefore, as many features as possible can be extracted from the variable condition. Here, the variable condition includes a relative position of the nozzle with respect to the substrate W, with the relative position changing over time. The first convolutional neural network CNN1 extracts the features using the plurality of filters, thereby extracting more features including time elements in regard to the change in relative position of the nozzle with respect to the substrate W. While being set to twice of the number of filters of the convolution layer of the first layer L1 here by way of example, the number of filters of the convolution layer of the second layer SL does not have to be twice of the number of filters of the convolution layer of the first layer L1. The number of filters of the convolution layer of the second layer L2 is only required to be larger than the number of filters of the convolution layer of the first layer L1. Further, the number of filters of the convolution layer of the third layer L3 does not have to be twice of the number of filters of the convolution layer of the second layer L2. The number of filters of the convolution layer of the third layer L3 is only required to be larger than the number of filters of the convolution layer of the second layer L2.

The fully-connected neural network NN includes a plurality of layers. In the example of FIG. 6, the fully-connected neural network NN includes two layers, which are, a layer ba on the input side and a layer bb on the output side. In the example of FIG. 6, each layer includes a plurality of nodes. While five nodes are shown in the layer ba and four nodes are shown in the layer bb in the example of FIG. 6, the number of nodes is not limited to these. The number of nodes of the layer ba is set equal to the sum of the number of nodes on the output side of the first convolutional neural network CNN1 and the number of fixed conditions. The number of nodes of the layer bb is set equal to the number of nodes on the input side of the second convolutional neural network CNN2. The output of a node of the layer ba is connected to the input of a node of the layer bb. A parameter includes a coefficient for weighting the output of a node of the layer ba. One or a plurality of intermediate layers may be provided between the layer ba and the layer bb.

The second convolutional neural network CNN2 includes a plurality of layers. In the present embodiment, the second convolutional neural network CNN2 includes three layers. In the second convolutional neural network CNN2, a fourth layer L4, a fifth layer L5 and a sixth layer L6 are provided in this order from the input side (upper layer side) to the output side (lower layer side). While the three layers are included as a plurality of layers in the description in the present embodiment, three or more layers may be included.

Each of the fourth layer L4, the fifth layer L5 and the sixth layer L6 includes a convolution layer and a pooling layer. The convolution layer includes a plurality of filters. In the convolution layer, a plurality of filters are used. The pooling layer compresses the output of the convolution layer. The number of filters of the convolution layer of the fifth layer L5 is set to ½ times of the number of filters of the convolution layer of the fourth layer L4. The number of filters of the convolution layer of the sixth layer L6 is set to ½ times of the number of filters of the convolution layer of the fifth layer L5. Therefore, as many features as possible can be extracted from the etching profile. The etching profile is represented by the difference E[n] between the film thickness obtained before a process and the film thickness obtained after the process at each of a plurality of positions P[n] (n is an integer equal to or larger than 1) in the radial direction of the substrate W. Therefore, a plurality of processing amounts in the etching profile vary according to the change of the position in the radial direction of the substrate W. The second convolutional neural network CNN2 extracts the features using the plurality of filters, thereby extracting more features including elements of position in the radial direction of the substrate W in regard to the change in processing amount. While being set to ½ of the number of filters of the convolution layer of the fourth layer L4 here by way of example, the number of filters of the convolution layer of the fifth layer L5 does not have to be ½ of the number of filters of the convolution layer of the fourth layer L4. The number of filters of the convolution layer of the fifth layer L5 is only required to be smaller than the number of filters of the convolution layer of the fourth layer L4. Further, the number of filters of the convolution layer of the sixth layer L6 does not have to be ½ of the number of filters of the convolution layer of the fifth layer L5. The number of filters of the convolution layer of the sixth layer L6 is only required to be smaller than the number of filters of the convolution layer of the fifth layer L5.

When a variable condition and fixed conditions that are input data are input to the learning model, the learning model predicts an etching profile. The etching profile predicted by this learning model is one example of a second processing amount. The difference between the etching profile predicted by the learning model and an etching profile which is the ground truth data is calculated as an error. Then, the learning model learns such that the error is reduced. For example, by using back-propagation method, the learning model updates the values of the plurality of filters of the first convolutional neural network CNN1, weight parameters defined by the plurality of nodes of the fully-connected neural network NN and the plurality of filters of the second convolutional neural network CNN2.

Referring back to FIG. 4, the information processing apparatus 100 includes a processing condition determiner 151, a prediction device receiver 155, a predictor 159, an evaluator 161 and a processing condition transmitter 163. The functions included in the information processing apparatus 100 are implemented by execution, by the CPU 101 included in the information processing apparatus 100, of a processing condition determining program stored in the RAM 102. The prediction device receiver 155 receives a prediction device transmitted from the training device 200 and outputs the received prediction device to the predictor 159.

The processing condition determiner 151 determines processing conditions for the substrate W to be processed by the substrate processing apparatus 300, and outputs a variable condition included in the processing conditions, and fixed conditions included in the processing conditions.

The predictor 159 predicts an etching profile based on the variable condition and the fixed conditions. Specifically, the predictor 159 inputs the variable condition and the fixed conditions received from the processing condition determiner 151 to the prediction device, and outputs the etching profile output by the prediction device to the evaluator 161.

The evaluator 161 evaluates the etching profile received from the predictor 159 and outputs the evaluation result to the processing condition determiner 151. In detail, the evaluator 161 acquires the film-thickness characteristic obtained before the substrate W to be processed by the substrate processing apparatus 300 is processed. The evaluator 161 calculates the film-thickness characteristic predicted to be obtained after the etching process based on the etching profile received from the predictor 159 and the film-thickness characteristic obtained before the substrate W is processed, and compares the calculated film-thickness characteristic with a target film-thickness characteristic. When the comparison result satisfies an evaluation criterion, the processing conditions determined by the processing condition determiner 151 are output to the processing condition transmitter 163. For example, the evaluator 161 calculates a deviation characteristic and determines whether the deviation characteristic satisfies the evaluation criterion. The deviation characteristic is the difference between the film-thickness characteristic of the substrate W obtained after the etching process and the target film-thickness characteristic. The evaluation criterion can be arbitrarily defined. For example, the evaluation criterion may be that the maximum value of difference in regard to the deviation characteristic is equal to or smaller than a threshold value, or that the average of differences is equal to or smaller than the threshold value.

The processing condition transmitter 163 transmits the processing conditions determined by the processing condition determiner 151 to the control device 10 of the substrate processing apparatus 300. The substrate processing apparatus 300 processes the substrate W according to the processing conditions.

In a case in which the evaluation result does not satisfy the evaluation criterion, the evaluator 161 outputs the evaluation result to the processing condition determiner 151. The evaluation result includes the difference between a film-thickness characteristic predicted to be obtained after the etching process and a target film-thickness characteristic.

In response to receiving the evaluation result from the evaluator 161, the processing condition determiner 151 determines new processing conditions for prediction to be made by the predictor 159. Using design of experiments, pairwise testing or Bayesian inference, the processing condition determiner 151 selects one of a plurality of variable conditions that are prepared in advance and determines processing conditions including a selected variable condition and fixed conditions as new processing conditions for prediction to be made by the predictor 159.

The processing condition determiner 151 may search for processing conditions using Bayesian inference. In a case in which a plurality of evaluation results are output by the evaluator 161, a plurality of sets each of which includes processing conditions and an evaluation result are obtained. Based on the likelihood of the etching profile for each of the plurality of sets, the processing conditions that cause the film thickness to be uniform or the processing conditions that cause the difference between a film-thickness characteristic predicted to be obtained after an etching process and a target film-thickness characteristic to be minimum are searched.

Specifically, the processing condition determiner 151 searches for the processing conditions that cause an objective function to be minimized. The objective function is a function representing the uniformity of film thickness of a film or a function representing the coincidence between the film-thickness characteristic of a film and a target film-thickness characteristic. For example, the objective function is a function that represents the difference between the film-thickness characteristic predicted to be obtained after the etching process and a target film-thickness characteristic using a parameter. The parameter here is the corresponding variable condition. The corresponding variable condition is a variable condition used for predicting an etching profile by the prediction device. The processing condition determiner 151 selects a variable condition which is a parameter determined by search among a plurality of variable conditions, and determines new processing conditions including the selected variable condition and fixed conditions.

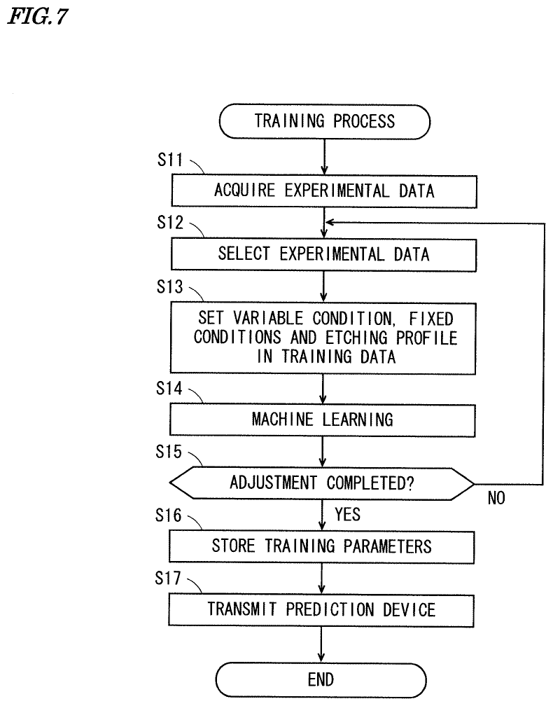

FIG. 7 is a flowchart showing one example of a flow of a training process. The training process is a process executed by the CPU 201 included in the training device 200 when the CPU 201 executes a training program stored in the RAM 202.

With reference to FIG. 7, the CPU 201 included in the training device 200 acquires experimental data. The CPU 201 controls the input-output I/F 107 to acquire the experimental data from the substrate processing apparatus 300 (step S11). The experimental data may be acquired when the experimental data recorded in a recording medium such as the CD-ROM 209 is read by the storage device 104. A plurality of experimental data sets are acquired here. The experimental data sets include processing conditions and the film-thickness characteristics of a film formed on the substrate W obtained before and after a process. The film-thickness characteristic is indicated by the film thickness of the film formed on the substrate W at each of a plurality of different positions in the radial direction of the substrate W.

In the next step S12, an experimental data set that is subjected to a process is selected, and the process proceeds to the step S13. In the step S13, a variable condition included in the experimental data set, fixed conditions and an etching profile are set in training data. The etching profile is the difference between the film-thickness characteristic of the film that is obtained before a process and included in the experimental data set, and the film-thickness characteristic of the film that is obtained after the process and included in the experimental data set. The training data includes input data and ground truth data. In the present embodiment, the variable condition included in the experimental data set and the fixed conditions are set in the input data, and the etching profile is set in the ground truth data.

In the next step S14, the CPU 201 causes a learning model to execute machine learning, and the process proceeds to the step S15. The input data is input to the learning model, and filters and parameters are determined such that the error between the output of the learning model and the ground truth data is reduced. This adjusts the filters and the parameters of the learning model.

In the step S15, whether adjustment has completed is determined. Training data used for evaluation of the learning model is prepared in advance, and the performance of the learning model is evaluated using the training data for evaluation. In a case in which the evaluation result satisfies a predetermined evaluation criterion, it is determined that adjustment is completed. If the evaluation result does not satisfy the evaluation criterion (NO in the step S15), the process returns to the step S12. If the evaluation result satisfies the evaluation criterion (YES in the step S15), the process proceeds to the step S16.

In a case in which the process returns to the step S12, an experimental data set that has not been selected as being subjected to a process is selected from the experimental data sets acquired in the step S11. In the loop of the step S12 to the step S15, the CPU 201 causes a learning model to execute machine learning using a plurality of training data sets. This adjusts the filters and the parameters of the learning model to appropriate values. In the step S16, the training parameters of the trained model are stored. In the step S17, the trained model is set in a prediction device, the prediction device is transmitted to the information processing apparatus 100, and the process ends. The CPU 201 controls the input-output I/F 107 and transmits the prediction device to the information processing apparatus 100.

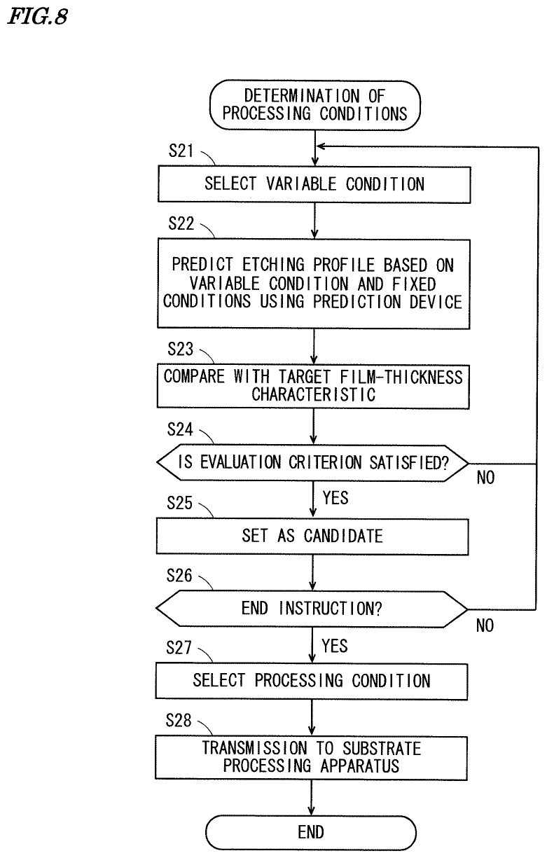

FIG. 8 is a flowchart showing one example of a flow of a processing condition determining process. The processing condition determining process is a process executed by the CPU 101 when the CPU 101 included in the information processing apparatus 100 executes the processing condition determining program stored in the RAM 102.

With reference to FIG. 8, the CPU 101 included in the information processing apparatus 100 selects one of a plurality of variable conditions that are prepared in advance (step S21), and the process proceeds to the step S22. Using design of experiments method, pairwise testing, Bayesian inference or the like, one of the plurality of variable conditions prepared in advance is selected.

In the step S22, an etching profile is predicted based on the variable condition and fixed conditions using a prediction device, and the process proceeds to the step S23. The variable condition and the fixed conditions are input to the prediction device, and the etching profile output by the prediction device is acquired. In the step S23, the film-thickness characteristic obtained after a process is compared with a target film-thickness characteristic. Based on the film-thickness characteristic obtained before a process for the substrate W to be processed by the substrate processing apparatus 300 and the etching profile predicted in the step S22, the film-thickness characteristic to be obtained after the substrate W is processed is calculated. Then, the film-thickness characteristic obtained after the process is compared with the target film-thickness characteristic. Here, the difference between the film-thickness characteristic obtained after the substrate W is processed and the target film-thickness characteristic is calculated.

In the step S24, whether the comparison result satisfies an evaluation criterion is determined. If the comparison result satisfies the evaluation criterion (YES in the step S24), the process proceeds to the step S25. If not, the process returns to the step S21. For example, in a case in which the maximum value for the difference is equal to or smaller than a threshold value, it is determined that the evaluation criterion is satisfied. Further, in a case in which the average value for the difference is equal to or smaller than a threshold value, it is determined that the evaluation criterion is satisfied.

In the step S25, processing conditions including the variable condition selected in the step S21 are set as candidates of processing conditions for driving the substrate processing apparatus 300, and the process proceeds to the step S26. In the step S26, whether an instruction for ending a search has been accepted is determined. If an end instruction provided by the user who operates the information processing apparatus 100 is accepted, the process proceeds to the step S27. If not, the process returns to the step S21. Instead of the end instruction input by the user, whether a predetermined number of processing conditions have been set as candidates may be determined.

In the step S27, one of the one or more processing conditions set as the candidates is selected, and the process proceeds to the step S28. One of the one or more processing conditions set as the candidates may be selected by the user who operates the information processing apparatus 100. This widens the range of selection for the user. Further, a variable condition according to which the nozzle work can be performed most simply may be automatically selected from among variable conditions included in a plurality of processing conditions. The variable condition according to which the nozzle work is performed most simply can be a variable condition according to which the nozzle work is performed with the smallest number of positions at which the velocity is changed, for example. Thus, a plurality of variable conditions can be presented in regard to a processing result for the complicated nozzle work for processing the substrate W. When a variable condition according to which the nozzle is easily controlled is selected from among a plurality of variable conditions, the control of the substrate processing apparatus 300 is facilitated.

In the step S28, the processing conditions including the variable condition determined in the step S28 are transmitted to the substrate processing apparatus 300, and the process ends. The CPU 101 controls the input-output I/F 107 and transmits the processing conditions to the substrate processing apparatus 300. In a case in which receiving the processing conditions from the information processing apparatus 100, the substrate processing apparatus 300 processes the substrate W according to the processing conditions.

### 4. Specific Examples

In the present embodiment, a variable condition is the time-series data that is sampled at sampling intervals of 0.01 seconds with a processing period of time for the nozzle work being 60 seconds. The variable condition includes 6001 values. Therefore, the variable condition can express a complicated nozzle work. In particular, the nozzle work having the relatively large number of positions at which the moving velocity of the nozzle is changed can be accurately represented using a variable condition. In contrast, because the number of dimensions of a variable condition is large, in a case in which a model of a fully-connected neural network executes machine learning using the time-series data of the variable condition, overfitting may occur.

The prediction device generator 265 in the present embodiment causes a learning model including the convolutional neural network shown in FIG. 6 to execute machine learning using a variable condition and fixed conditions. The inventor of the present invention has discovered through an experiment that, in a case in which a prediction device causes the learning model shown in FIG. 6 to learn the variable condition including 6001 values and indicating a complicated nozzle work, and fixed conditions, a desired result is obtained as an etching profile predicted by a prediction device.

In the present embodiment, when searching for processing conditions, the processing condition determiner 151 searches for processing conditions respectively corresponding to different etching profiles. Therefore, the processing conditions corresponding to the plurality of different etching profiles are selected. Therefore, the processing condition determiner 151 can efficiently search for processing conditions with which the target etching profile is predicted to be obtained from among a plurality of processing conditions.

While being set to 0.01 seconds by way of example, the sampling interval is not limited to this. The sampling interval may be longer or shorter than this. For example, the sampling interval may be 0.1 seconds or 0.005 seconds.

### 5. Other Embodiments

(1) In the above-mentioned embodiment, the training device 200 generates a prediction device based on training data. The training device 200 may additionally train a prediction device. After a prediction device is generated, the training device 200 acquires the film-thickness characteristics of a film obtained before and after the substrate W is processed by the substrate processing apparatus 300, and processing conditions. Then, the training device 200 generates training data based on the film-thickness characteristics of the film obtained before and after the process, and the processing conditions, and causes the prediction device to execute machine learning, thereby additionally training the prediction device. While not changing the configuration of a neural network constituting the prediction device, the additional training adjusts parameters.

Because the prediction device executes machine learning using the information obtained as a result of the process actually executed on the substrate W by the substrate processing apparatus 300, the accuracy of the prediction device can be improved. Further, the number of training data sets used for generating the prediction device can be reduced as much as possible.

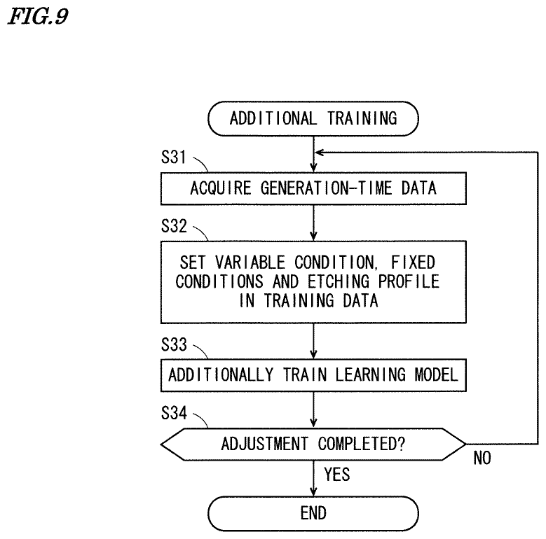

FIG. 9 is a flowchart showing one example of a flow of an additional training process. The additional training process is a process executed by the CPU 201 included in the training device 200 when the CPU 201 executes an additional training program stored in the RAM 202. The additional training program is part of the training program.

With reference to FIG. 9, the CPU 201 included in the training device 200 acquires generation-time data (step S031), and the process proceeds to the step S32. The generation-time data includes processing conditions for a process executed on the substrate W by the substrate processing apparatus 300 and film-thickness characteristics of a film obtained before and after the process. The CPU 201 controls the input-output I/F 107 and acquires the generation-time data from the substrate processing apparatus 300. The generation-time data may be acquired when experimental data recorded in a recording medium such as the CD-ROM 209 is read by the storage device 104.

In the step S32, a variable condition, fixed conditions included in the processing conditions of the generation-time data, and an etching profile are set in training data. The etching profile is the difference between the film-thickness characteristic of a film that is obtained before a process and included in the generation-time data and the film-thickness characteristic of the film that is obtained after the process and included in the generation-time data. The variable condition and the fixed conditions included in the processing conditions are set in input data. The etching profile is set as ground truth data.

In the next step S33, the CPU 201 additionally trains the prediction device, and the process proceeds to the step S34. The input data is input to the prediction device, and filters and parameters are determined such that the error between the output of the prediction device and the ground truth data is reduced. Thus, filters and parameters of the prediction device are further adjusted.

In the step S34, whether adjustment has completed is determined. The performance of the prediction device is evaluated using training data for evaluation. In a case in which the evaluation result satisfies a predetermined additional training evaluation criterion, it is determined that adjustment is completed. The additional training evaluation criterion is a criterion higher than an evaluation criterion used in a case in which a prediction device is generated. If the evaluation result does not satisfy the additional training evaluation criterion (NO in the step S34), the process returns to the step S31. If the evaluation result satisfies the additional training evaluation criterion (YES in the step S34), the process ends.

(2) The training device 200 may generate a distillation model obtained when a new learning model executes machine training, by using distillation data that includes processing conditions determined by the information processing apparatus 100 and an etching profile predicted by a prediction device based on the processing conditions. This facilitates preparation of data for training a new learning model.

(3) In the present embodiment, in training data used for generation of a prediction device, input data includes a variable condition and fixed conditions. The present invention is not limited to this. The input data may include only a variable condition, and does not have to include fixed conditions.

(4) While the relative positions of the nozzle 311 and the substrate W with respect to each other are shown as one example of a variable condition in the present embodiment, the present invention is not limited to this. In a case in which at least one of a temperature of the etching liquid, a concentration of the etching liquid, a flow rate of the etching liquid, and the number of rotations of the substrate W varies over time, they may be a variable condition. Further, the number of types of variable conditions is not limited to 1, and may be 2 or more.

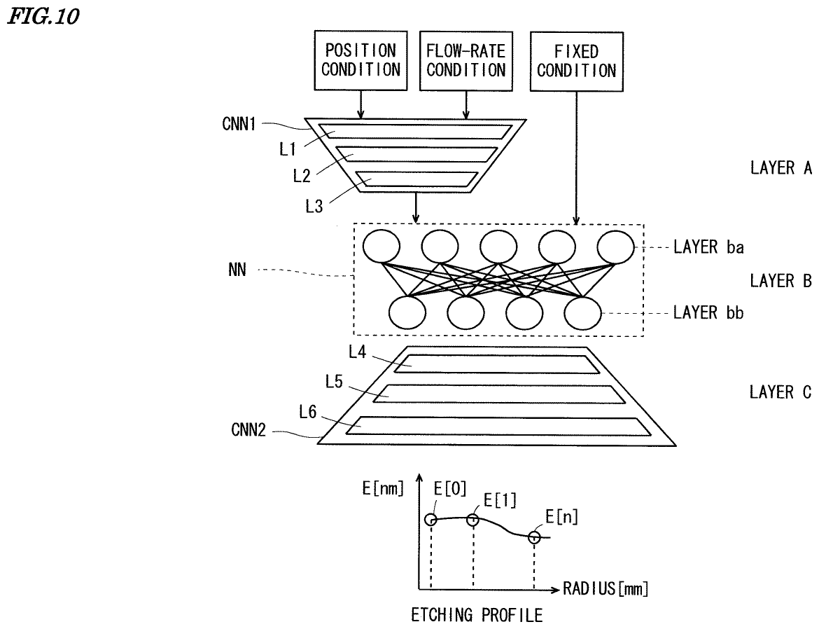

FIG. 10 is a first diagram for explaining a learning model according to another embodiment. Here, a flow rate of the etching liquid to be discharged from the nozzle varies over time, by way of example. In this case, the variable condition includes the flow rate of the etching liquid that varies over time. In this case, the learning model shown in FIG. 10 is used. The learning model shown in FIG. 10 is different from the learning model shown in FIG. 6 in that variable conditions input to a first convolutional neural network CNN1 include a position condition indicating a relative position of the nozzle with respect to the substrate, with the relative position varying over time, and a flow-rate condition indicating a flow rate of the etching liquid which varies over time. Therefore, the first convolutional neural network CNN1 executes a convolution process of two channels.

In this case, the position condition and the flow-rate condition respectively indicate a relative position of the nozzle with respect to the substrate and a flow rate of the etching liquid, at the same point in time. Therefore, when the position condition and the flow-rate condition are learned, the position condition and the flow-rate condition can be learned with time information. Further, because the single first convolutional neural network CNN1 is used, it can suppress the number of training parameters and can suppress overfitting.

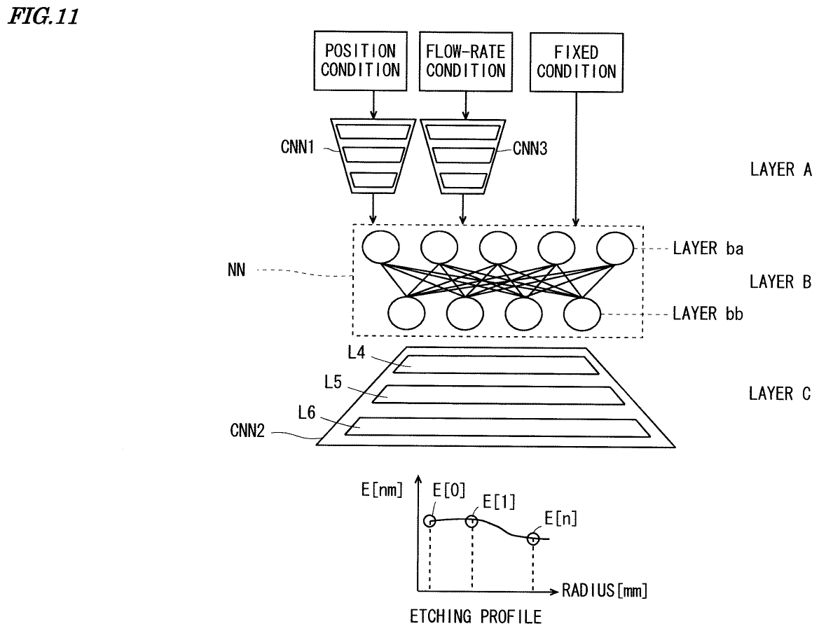

Further, in the learning model, the position condition and the flow-rate condition may be processed by different convolutional neural networks. FIG. 11 is a second diagram for explaining a learning model according to another embodiment. With reference to FIG. 11, a first convolutional neural network CNN1 that processes a nozzle condition and a third convolutional neural network CNN3 that processes a flow-rate condition are provided on the input side of a fully-connected neural network NN.

(5) While the learning model includes the first convolutional neural network CNN1, the fully-connected neural network NN and the second convolutional neural network CNN2 in the above-mentioned embodiment, the present invention is not limited to this. For example, in a prediction device, one or both of the fully-connected neural network NN and the second convolutional neural network CNN2 do not have to be provided.

(6) While the information processing apparatus 100 and the training device 200 are separated from the substrate processing apparatus 300 by way of example, the present invention is not limited to this. The information processing apparatus 100 may be incorporated in the substrate processing apparatus 300. Further, the information processing apparatus 100 and the training device 200 may be incorporated in the substrate processing apparatus 300. While being separate apparatuses, the information processing apparatus 100 and the training device 200 may be configured as an integrated apparatus.

### 6. Effects of Embodiments

In the training device 200 of the above-mentioned embodiment, because a variable condition is a value that varies over time, it is possible to extract a feature that takes time elements into consideration by using the first convolutional neural network CNN1. Further, because it is possible to suppress the number of training parameters by causing the first convolutional neural network CNN1 to learn, generalization performance of a learning model can be improved.

Further, because a processing amount is defined for each of a plurality of different positions in the radial direction of a substrate, a feature that takes elements of position in the radial direction of the substrate into consideration is extracted when the second convolutional neural network CNN2 learns the processing amount. Further, it is possible to suppress the number of training parameters and improve generalization performance of a learning model.

Further, the fully-connected neural network NN is provided between the first convolutional neural network CNN1 and the second convolutional neural network CNN2. In this case, the number of outputs of the first convolutional neural network CNN1 and the number of inputs of the second convolutional neural network CNN2 can be adjusted by the fully-connected neural network NN. Further, because the number of outputs of the first convolutional neural network CNN1 and the number of inputs of the second convolutional neural network CNN2 can be adjusted by the fully-connected neural network NN, it is possible to proceed machine learning well even when the number of outputs of the first convolutional neural network CNN1 and the number of inputs of the second convolutional neural network CNN2 do not match. Further, because the number of outputs of the first convolutional neural network CNN1 and the number of inputs of the second convolutional neural network CNN2 do not have to match, machine learning can be executed using training data with a larger number of dimensions. Therefore, machine learning can be executed using a variable condition having a larger number of dimensions. Further, it is possible to execute machine learning using a fixed condition with a larger number of dimensions, and it is possible to execute machine learning using processing conditions with a larger number of types of conditions, with the processing conditions being conditions for driving the substrate processing apparatus.

Further, because the number of filters increases from the upper layer toward the lower layer in the first convolutional neural network CNN1, it is possible to extract many features of a variable condition. Further, because the number of filters decreases from the upper layer toward the lower layer in the second convolutional neural network CNN2, it is possible to extract many features that take the position of each of a plurality of processing amounts into consideration. As a result, it is possible to improve the generalization performance of the training device 200.

Further, because a learning model includes the first convolutional neural network CNN1, even in a case in which the number of data sets of a variable condition is large, it is possible to generate a learning model with improved generalization performance.

### 7. Correspondences Between Constituent Elements in Claims and Parts in Preferred Embodiments

The substrate W is an example of a substrate, the etching liquid is an example of a processing liquid, the substrate processing apparatus 300 is an example of a substrate processing apparatus, the experimental data acquirer 261 is an example of an experimental data acquirer, the prediction device is one example of a learning model, and the prediction device generator 265 is an example of a model generator. Further, the information processing apparatus 100 is an example of an information processing apparatus, the variable condition generator 251 is an example of a variable condition generator, the nozzle 311 is one example of a nozzle that supplies a processing liquid to a substrate, the nozzle moving mechanism 301 is an example of a mover, the predictor 159, the evaluator 161 and the processing condition determiner 151 are examples of a processing condition determiner.

### 8. Overview of Embodiments

(Item 1) A training device according to one aspect of the present invention includes an experimental data acquirer that acquires a first processing amount indicating a difference between a film thickness obtained before a process for a film and a film thickness obtained after the process for the film, after a substrate processing apparatus is driven according to processing conditions including a variable condition that varies over time and executes the process for the film, the substrate processing apparatus processing the film by supplying a processing liquid to the substrate on which the film is formed, and a model generator that generates a learning model, the learning model executing machine learning using training data that includes the variable condition and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus, wherein the learning model includes a first convolutional neural network.

With the training device according to item 1, because the variable condition is a value that varies over time, it is possible to extract a feature that takes time elements into consideration by using the first convolutional neural network. Further, because it is possible to suppress the number of training parameters by using the convolutional neural network, generalization performance of the learning model can be improved. As a result, it is possible to provide the training device suitable for machine learning using a condition for a substrate process, with the condition changing over time.

(Item 2) The training device according to item 1, wherein each of the first processing amount and the second processing amount may be a difference between a film thickness obtained before the process for the film and a film thickness obtained after the process for the film in regard to each of a plurality of different positions in a radial direction of the substrate, and the learning model may further include a second convolutional neural network that outputs the first processing amount or the second processing amount.

With the training device according to item 2, because the first and second processing amounts are defined for each of a plurality of different positions in the radial direction of the substrate, a feature that takes elements of the positions in the radial direction of the substrate into consideration is extracted when the convolutional neural network is trained using the first or second processing amount. Further, it is possible to suppress the number of training parameters and improve generalization performance of the learning model.

(Item 3) The training device according to item 2, wherein the learning model may further include a fully-connected neural network to which output of the first convolutional neural network and fixed conditions other than the variable condition out of the processing conditions, and the second convolutional neural network may receive output of the fully-connected neural network.

With the training device according to item 3, the fully-connected neural network is provided between the first convolutional neural network and the second convolutional neural network. In this case, the number of features to be output from the first convolutional neural network and the number of features to be input to the second convolutional neural network can be adjusted by the fully-connected neural network.

(Item 4) The training device according to item 2 or 3, wherein in regard to a count of filters used in each of a plurality of layers of the first convolutional neural network, a count of filters used in a lower layer may be twice of a count of layers used in an upper layer, and in regard to a count of filters used in each of a plurality of layers of the second convolutional neural network, a count of filters used in a lower layer may be ½ of a count of filters used in an upper layer.

With the training device according to item 4, because the number of filters increases from the upper layer toward the lower layer in the first convolutional neural network, it is possible to extract many features of the variable condition. Further, because the number of filters decreases from the upper layer toward the lower layer in the second convolutional neural network, it is possible to extract many features of a plurality of processing amounts. As a result, it is possible to improve the accuracy of the training device.

(Item 5) The training device according to any one of items 1 to 4, wherein the substrate processing apparatus may supply a processing liquid to a substrate by moving a nozzle that supplies the processing liquid to the substrate, and the variable condition may include a nozzle movement condition indicating a relative position of the nozzle with respect to the substrate, with the relative position varying over time.

With the training device according to item 5, a nozzle movement condition is input to the first convolutional neural network. Therefore, even in a case in which the number of data sets of the nozzle movement condition is large, it is possible to generate a learning model with improved generalization performance.

(Item 6) The substrate processing apparatus according to item 5, wherein the variable condition may further include a discharge flow-rate condition indicating a flow rate of the processing liquid to be discharged from the nozzle, with the flow rate changing over time.

With the training device according to item 6, even in a case in which the number of data sets of the discharge flow-rate condition is large, it is possible to generate a learning model with improved generalization performance.

(Item 7) A substrate processing apparatus according to another aspect of the present invention managing an information processing apparatus, wherein the substrate processing apparatus processes a film by supplying a processing liquid to a substrate on which the film is formed according to processing conditions including a variable condition that varies over time, and includes a processing condition determiner that determines processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus, the learning model includes a first convolutional neural network and is an inference model that has executed machine learning using training data, with the training data including the variable condition included in the processing conditions according to which the substrate processing apparatus has executed a process for the film, and a first processing amount indicating a difference between a film thickness obtained before the process for the film and a film thickness obtained after the process for the film in regard to the film that is formed on the substrate and has been processed by the substrate processing apparatus, and the processing condition determiner, in a case in which a temporary variable condition is provided to the learning model and the second processing amount predicted by the learning model satisfies an allowable condition, determines processing conditions including the temporary variable condition as processing conditions for driving the substrate processing apparatus.

With the information processing apparatus according to item 7, in a case in which the temporary variable condition that varies over time is provided to the learning model and the processing amount predicted by the learning model satisfies an allowable condition, the processing conditions including the temporary variable condition are determined as processing conditions for driving the substrate processing apparatus. Therefore, a plurality of temporary variable conditions can be determined for the processing amount that satisfies the allowable condition. As a result, it is possible to present a plurality of processing conditions for a processing result of a complicated process of processing the substrate.

(Item 8) A substrate processing apparatus may include the information processing apparatus according to item 7.

With the substrate processing apparatus according to item 8, it is possible to present a plurality of processing conditions for a processing result of a complicated process of processing a substrate.

(Item 9) A substrate processing system according to another aspect of the present invention that manages a substrate processing apparatus, includes a training device and an information processing apparatus, wherein the substrate processing apparatus processes a film by supplying a processing liquid to a substrate on which the film is formed according to processing conditions including a variable condition that varies over time, the training device includes an experimental data acquirer that acquires a first processing amount indicating a difference between a film thickness obtained before a process for the film and a film thickness obtained after the process for the film, after the substrate processing apparatus is driven according to processing conditions and executes the process for the film formed on the substrate, and a model generator that generates a learning model, the learning model executing machine learning using training data that includes the variable condition and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus, the learning model includes a first convolutional neural network, the information processing apparatus includes a processing condition determiner that determines processing conditions for driving the substrate processing apparatus using the learning model generated by the training device, and the processing condition determiner, in a case in which a temporary variable condition is provided to the learning model generated by the training device and the second processing amount predicted by the learning model satisfies an allowable condition, determines processing conditions including the temporary variable condition as processing conditions for driving the substrate processing apparatus.

With the substrate processing system according to item 9, it is suitable for machine learning using a condition for a substrate process, with the condition changing over time, and it is possible to present a plurality of processing conditions for a processing result of a complicated process of processing a substrate.

(Item 10) A training method according to another aspect of the present invention of causing a computer to execute the processes of acquiring a first processing amount indicating a difference between a film thickness obtained before a process for a film and a film thickness obtained after the process for the film, after a substrate processing apparatus is driven according to processing conditions including a variable condition that varies over time and executes the process for the film, the substrate processing apparatus processing the film by supplying a processing liquid to the substrate on which the film is formed, and generating a learning model, the learning model executing machine learning using training data that includes the variable condition and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus, wherein the learning model includes a first convolutional neural network.

With the training method according to item 10, the learning model includes a convolutional neural network. Therefore, it is possible to provide the training method suitable for machine learning using a condition for a substrate process, with the condition changing over time.

(Item 11) A processing condition determining method according to another aspect of the present invention executed by a computer that manages a substrate processing apparatus, wherein the substrate processing apparatus processes a film by supplying a processing liquid to a substrate on which the film is formed according to processing conditions including a variable condition that varies over time, the processing condition determining method includes a process of determining processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus, the learning model includes a first convolutional neural network and is an inference model that has executed machine learning using training data, with the training data including the variable condition included in the processing conditions according to which the substrate processing apparatus has executed a process for the film, and a first processing amount indicating a difference between a film thickness obtained before the process for the film and a film thickness obtained after the process for the film in regard to the film that is formed on the substrate and has been processed by the substrate processing apparatus, and the process of determining processing conditions, in a case in which a temporary variable condition is provided to the learning model and the second processing amount predicted by the learning model satisfies an allowable condition, includes determining processing conditions including the temporary variable condition as processing conditions for driving the substrate processing apparatus.

With the processing condition determining method according to item 11, it is possible to present a plurality of processing conditions for a result of a complicated process of processing a substrate.

1. training device comprising:
an experimental data acquirer that acquires a first processing amount indicating a difference between a film thickness obtained before a process for a film and a film thickness obtained after the process for the film, after a substrate processing apparatus is driven according to processing conditions including a variable condition that varies over time and executes the process for the film, the substrate processing apparatus processing the film by supplying a processing liquid to the substrate on which the film is formed; and
a model generator that generates a learning model, the learning model executing machine learning using training data that includes the variable condition and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus, wherein the learning model includes a first convolutional neural network.

2. The training device according to claim 1, wherein
each of the first processing amount and the second processing amount is a difference between a film thickness obtained before the process for the film and a film thickness obtained after the process for the film in regard to each of a plurality of different positions in a radial direction of the substrate, and
the learning model further includes a second convolutional neural network that outputs the first processing amount or the second processing amount.

3. The training device according to claim 2, wherein
the learning model further includes a fully-connected neural network to which output of the first convolutional neural network and fixed conditions other than the variable condition out of the processing conditions, and
the second convolutional neural network receives output of the fully-connected neural network.

4. The training device according to claim 2, wherein
in regard to a count of filters used in each of a plurality of layers of the first convolutional neural network, a count of filters used in a lower layer is twice of a count of layers used in an upper layer, and
in regard to a count of filters used in each of a plurality of layers of the second convolutional neural network, a count of filters used in a lower layer is ½ of a count of filters used in an upper layer.

5. The training device according to claim 1, wherein
the substrate processing apparatus supplies a processing liquid to a substrate by moving a nozzle that supplies the processing liquid to the substrate, and
the variable condition includes a nozzle movement condition indicating a relative position of the nozzle with respect to the substrate, with the relative position varying over time.

6. The substrate processing apparatus according to claim 5, wherein
the variable condition further includes a discharge flow-rate condition indicating a flow rate of the processing liquid to be discharged from the nozzle, with the flow rate changing over time.

7. A substrate processing apparatus managing an information processing apparatus, wherein
the substrate processing apparatus
processes a film by supplying a processing liquid to a substrate on which the film is formed according to processing conditions including a variable condition that varies over time, and
includes a processing condition determiner that determines processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus,
the learning model includes a first convolutional neural network and is an inference model that has executed machine learning using training data, with the training data including the variable condition included in the processing conditions according to which the substrate processing apparatus has executed a process for the film, and a first processing amount indicating a difference between a film thickness obtained before the process for the film and a film thickness obtained after the process for the film in regard to the film that is formed on the substrate and has been processed by the substrate processing apparatus, and
the processing condition determiner, in a case in which a temporary variable condition is provided to the learning model and the second processing amount predicted by the learning model satisfies an allowable condition, determines processing conditions including the temporary variable condition as processing conditions for driving the substrate processing apparatus.

8. A substrate processing apparatus including the information processing apparatus according to claim 7.

9. A substrate processing system that manages a substrate processing apparatus, comprising a training device and an information processing apparatus, wherein
the substrate processing apparatus processes a film by supplying a processing liquid to a substrate on which the film is formed according to processing conditions including a variable condition that varies over time,
the training device includes
an experimental data acquirer that acquires a first processing amount indicating a difference between a film thickness obtained before a process for the film and a film thickness obtained after the process for the film, after the substrate processing apparatus is driven according to processing conditions and executes the process for the film formed on the substrate, and
a model generator that generates a learning model, the learning model executing machine learning using training data that includes the variable condition and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus,
the learning model includes a first convolutional neural network,
the information processing apparatus includes
a processing condition determiner that determines processing conditions for driving the substrate processing apparatus using the learning model generated by the training device, and
the processing condition determiner, in a case in which a temporary variable condition is provided to the learning model generated by the training device and the second processing amount predicted by the learning model satisfies an allowable condition, determines processing conditions including the temporary variable condition as processing conditions for driving the substrate processing apparatus.

10. A training method of causing a computer to execute the processes of:
acquiring a first processing amount indicating a difference between a film thickness obtained before a process for a film and a film thickness obtained after the process for the film, after a substrate processing apparatus is driven according to processing conditions including a variable condition that varies over time and executes the process for the film, the substrate processing apparatus processing the film by supplying a processing liquid to the substrate on which the film is formed; and
generating a learning model, the learning model executing machine learning using training data that includes the variable condition and the first processing amount corresponding to the processing conditions and predicting a second processing amount that indicates a difference between a film thickness obtained before the process for the film and a film thickness obtained after the process for the film in regard to the film formed on the substrate before being processed by the substrate processing apparatus, wherein
the learning model includes a first convolutional neural network.

11. A processing condition determining method executed by a computer that manages a substrate processing apparatus, wherein
the substrate processing apparatus processes a film by supplying a processing liquid to a substrate on which the film is formed according to processing conditions including a variable condition that varies over time,
the processing condition determining method includes a process of determining processing conditions for driving the substrate processing apparatus using a learning model, with the learning model predicting a second processing amount that indicates a difference between a film thickness obtained before a process for the film and a film thickness obtained after the process for the film in regard to the film formed on the substrate before being processed by the substrate processing apparatus,
the learning model includes a first convolutional neural network and is an inference model that has executed machine learning using training data, with the training data including the variable condition included in the processing conditions according to which the substrate processing apparatus has executed a process for the film, and a first processing amount indicating a difference between a film thickness obtained before the process for the film and a film thickness obtained after the process for the film in regard to the film that is formed on the substrate and has been processed by the substrate processing apparatus, and
the process of determining processing conditions, in a case in which a temporary variable condition is provided to the learning model and the second processing amount predicted by the learning model satisfies an allowable condition, includes determining processing conditions including the temporary variable condition as processing conditions for driving the substrate processing apparatus.
